(19) United States
(12) Patent Application Publication
(10) Pub. No.: US 2014/0314172 A1
(43) Pub. Date: Oct. 23, 2014

(54) STACKED COMPARATOR TOPOLOGY FOR MULTI-LEVEL SIGNALING

(71) Applicant: Samsung Display Co., Ltd., Yongin City (KR)

(72) Inventor: Mohammad Hekmat, Mountain View, CA (US)

(73) Assignee: Samsung Display Co., Ltd., Yongin City (KR)

(21) Appl. No.: 14/162,648

(22) Filed: Jan. 23, 2014

Related U.S. Application Data
(60) Provisional application No. 61/814,759, filed on Apr. 22, 2013.

(51) Int. Cl. H04L 27/06; H03M 5/20

(52) U.S. Cl. CPC H04L 27/06; H03M 5/20
USPC 375/287; 375/286

(57) ABSTRACT

A system and method for detecting signal levels in a multi-level signaling receiver. In one embodiment, a plurality of comparators, each including a differential pair, such as a differential pair of field-effect transistors (FETs) are assembled in a stacked configuration so that in some states current flows through FETs of the plurality of differential pairs in series, resulting in a reduction in power consumption.

### CROSS-REFERENCE TO RELATED APPLICATION(S)

The present application claims priority to and the benefit of Provisional Application No. 61/814,759, filed Apr. 22, 2013, entitled “STACKED COMPARATOR TOPOLOGY FOR MULTI-LEVEL SIGNALING”, the entire content of which is incorporated herein by reference.

### FIELD

The following description relates to multi-level signaling and more particularly to a low-power, high-speed system and method for receiving a signal employing multi-level signaling.

### BACKGROUND

When a digital signal is transmitted across a data bus using two levels, i.e., binary signaling, the signal switches between two values, representing a binary 0 or 1, respectively. For example, the voltage on a conductor, such as a wire or a printed wiring board trace, may be driven to a first value to signify a binary 0 and to a second value to signify a binary 1.

Data may be sent across a bus at a higher data throughput, for a given clock rate, using multi-level signaling. For example, in four-level signaling, which may be referred to as four-level pulse amplitude modulation (PAM-4), the voltage on conductor may take one of four values. In a PAM-4 receiver the received signal may then be converted, for each of the four voltage values, to a pair of bits, with a first value corresponding to binary 00, a second value corresponding to binary 01, a third value corresponding to binary 10, and a fourth value corresponding to binary 11, respectively. In other embodiments the correspondence between the voltage levels and pairs of bits may be different, or another parallel signaling scheme, such as one-hot encoding, or inverse one-hot encoding, may be used.

A multi-level receiver, which receives a multi-level signal as input and produces parallel binary signals as output, may be constructed with multiple comparators in parallel, which may be identical except for the threshold voltage to which each is connected. One input of each comparator may be connected to the received signal Vᵢₙ, and the other input may be connected to a threshold voltage.

Each comparator in such a multi-level receiver may be composed of a differential pair of transistors, with each transistor being connected to a resistor and to a shared current source. The current flowing through one of the resistors and one of the transistors in such a differential pair, and through the current source, dissipates power, and if there are several such comparators in a receiver then several times as much power is dissipated. Power consumption may be reduced by operating the comparators in a sequential comparison mode in which only one comparator is active at any given time, but this approach, while reducing power consumption, also reduces the speed at which the receiver is capable of operating, resulting in slower data transmission and, accordingly, a loss of at least some of the benefits of using multi-level signaling.

Thus, there is a need for a low-power, high-speed system and method for receiving a signal employing multi-level signaling.

### SUMMARY

Aspects of embodiments of the present invention relate to a system and method for detecting signal levels in a multi-level signaling scheme. In one embodiment, a plurality of comparators, each including a differential pair, such as a differential pair of field-effect transistors (FETs) are assembled in a stacked configuration so that in some states current flows through FETs of the plurality of differential pairs in series, resulting in a reduction in power consumption.

According to an embodiment of the present invention there is provided a system for receiving a multi-level signal, the system including: a system input connection; a first differential pair and a second differential pair; each of the first differential pair and the second differential pair including a first switch and a second switch, each of the first switch and the second switch including a first switching terminal, a second switching terminal, and a control terminal, the second switching terminal of the first switch connected to the second switching terminal of the second switch, the control terminal of the first switch of the first differential pair connected to the system input connection, the control terminal of the first switch of the second differential pair connected to the system input connection, the first terminal of the second switch of the first differential, pair connected to: the second switching terminal of the first switch of the second differential pair; and the second switching terminal of the second switch of the second differential pair.

In one embodiment, at least one of the first switch or the second switch is a semiconductor switch.

In one embodiment, at least one the first switch or the second switch is a field effect transistor (FET).

In one embodiment, at least one the first switch or the second switch is a bipolar junction transistor (BJT).

In one embodiment, the control terminal of the second switch of the first differential pair is connected to a voltage source at a first threshold voltage, and the control terminal of the first switch of the second differential pair is connected to a voltage source at a second threshold voltage.

In one embodiment, the first threshold voltage is greater than the second threshold voltage.

In one embodiment, the multi-level signal includes three adjacent levels, the first threshold voltage is half-way between a first adjacent pair of levels of the three adjacent levels, and the second threshold voltage is half-way between a second adjacent pair of levels of the three adjacent levels.

In one embodiment, the second switching terminal of the first switch of the first differential pair and the second switching terminal of the second switch of the first differential pair are connected to a first terminal of a current source; and the second terminal of the current source is connected to a first power supply connection.

In one embodiment, the first power supply connection is a ground connection of a power supply.

In one embodiment, the first switching terminal of the first switch of the first differential pair is connected to: a first system output connection; and a first terminal of a first load element; the first switching terminal of the first switch of the second differential pair is connected to: a second system output connection; and a first terminal of a second load element; a second terminal of the first load element is connected to a second power supply connection; and a second terminal of the second load element is connected to the second power supply connection.

In one embodiment, the second power supply connection is a positive connection of a power supply.

In one embodiment, at least one the first switch or the second switch is a semiconductor switch.

In one embodiment, at least one the first switch or the second switch is a field effect transistor (FET).

In one embodiment, at least one the first switch or the second switch is a bipolar junction transistor (BJT).

In one embodiment, the control terminal of the second switch of the first differential pair is connected to a voltage source at a first threshold voltage, and the control terminal of the first switch of the second differential pair is connected to a voltage source at a second threshold voltage.

In one embodiment, the second threshold voltage is greater than the first threshold voltage.

In one embodiment, the multi-level signal includes three adjacent levels, and the first threshold voltage is half-way between a first adjacent pair of levels of the three adjacent levels; and the second threshold voltage is half-way between a second adjacent pair of levels of the three adjacent levels.

In one embodiment, at least one of the first load element or the second load element is a resistor.

In one embodiment, at least one of the first load element or the second load element is a third switch, and the third switch includes a first switching terminal, a second switching terminal, and a control terminal, the control terminal of the third switch being connected to the first terminal of the third switch.

In one embodiment, the system includes a source terminal, a drain terminal, and a gate terminal, the drain terminal being the first switching terminal of the third switch, the source terminal being the second switching terminal of the third switch, and the gate being the control terminal of the third switch.

### BRIEF DESCRIPTION OF THE DRAWINGS

These and other features and advantages of the present invention will be appreciated and understood with reference to the specification, claims and appended drawings wherein:

FIG. 1A is a set of three eye diagrams illustrating binary data transmission at a first clock rate and at a second clock rate, and multi-level data transmission at the first clock rate;

FIG. 1B is a hybrid block-schematic diagram of a related art multi-level receiver;

FIG. 2 is a schematic diagram of a level detector according to an embodiment of the present invention;

FIG. 3 is a schematic diagram of a level detector in a first state of operation according to an embodiment of the present invention;

FIG. 4 is a schematic diagram of a level detector in a second state of operation according to an embodiment of the present invention;

FIG. 5 is a schematic diagram of a level detector in a third state of operation according to an embodiment of the present invention;

FIG. 6 is a schematic diagram of a level detector in a fourth state of operation according to an embodiment of the present invention;

FIG. 7 is a truth table illustrating inputs and outputs of an embodiment of the present invention; and

FIG. 8 is a display employing a multi-level transmitter and a multi-level receiver according to an embodiment of the present invention.

### DETAILED DESCRIPTION

The detailed description set forth below in connection with the appended drawings is intended as a description of exemplary embodiments of a stacked comparator topology for multi-level signaling provided in accordance with the present invention and is not intended to represent the only forms in which the present invention may be constructed or utilized. The description sets forth the features of the present invention in connection with the illustrated embodiments. It is to be understood, however, that the same or equivalent functions and structures may be accomplished by different embodiments that are also intended to be encompassed within the spirit and scope of the invention. As denoted elsewhere herein, like element numbers are intended to indicate like elements or features.

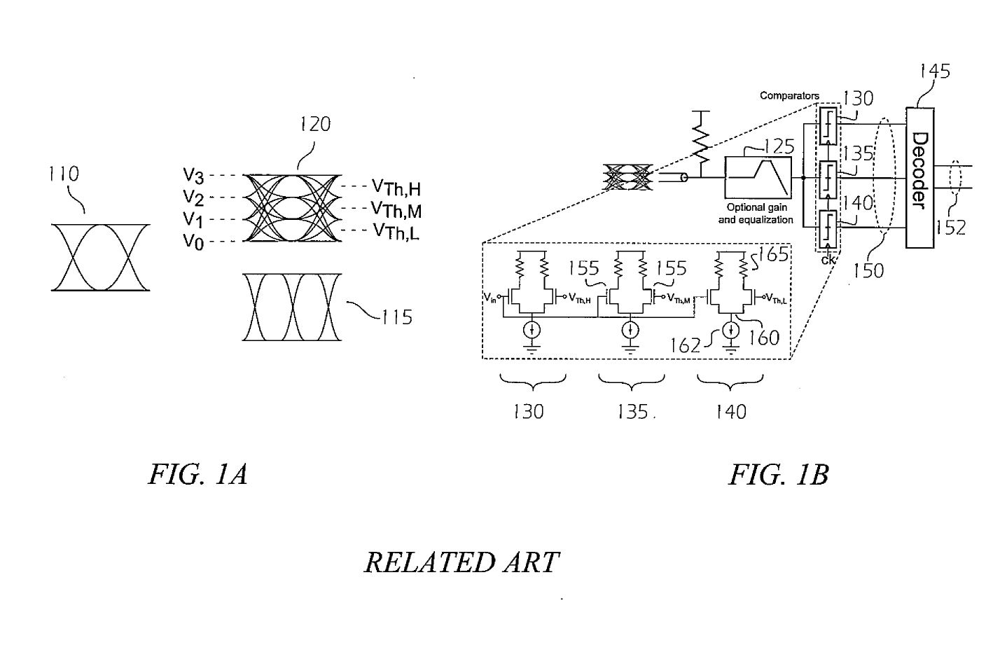

FIG. 1A, shows three eye diagrams, representing the transmission of digital data on an analog signal. A first eye diagram 110 shows data transmitted in a two-level or binary signaling scheme at a first clock rate and a first data rate. To increase the data rate, the system may be operated at a higher clock rate, i.e., with transitions spaced more closely in time, as illustrated in eye diagram 115, or multi-level signaling may be used, as illustrated in eye diagram 120. The eye diagram 120 shows four-level signaling, as may be used in PAM-4, for example.

In four-level signaling, such as PAM-4, the voltage on a signal conductor may take four values of increasing voltage, i.e., a first value, a second value, a third value, and a fourth value, which are referred to herein as V₀, V₁, V₂, and V₃. In a four-level receiver, a level detector may be used to distinguish between these for voltages, by comparing the received voltage to different threshold voltages. For example, to receive PAM-4, three threshold voltages may be used. The threshold voltages are referred to as V_{Th,H}, V_{Th,M}, and V_{Th,L}, respectively, and may be selected so that each is approximately half-way between two adjacent levels of the multi-level signaling scheme. The threshold voltage V_{Th,L} may be half-way between the first voltage value V₀ and the second voltage value V₁, the threshold voltage V_{Th,M} may be half-way between the second voltage value V₁ and the third voltage value V₂, and the threshold voltage V_{Th,H} may be half-way between the third voltage value V₂ and the fourth voltage value V₃.

Referring to FIG. 1B, a multi-level receiver may include optional gain and equalization circuitry 125, a level detector composed of a set of comparators 130, 135, 140, and a decoder 145. The output of the level detector may be a parallel digital signal with one-hot encoding, i.e., a parallel set of signals of which at most one represents a binary “1”, i.e., logic high, at any time. The decoder 145 may then convert the one-hot signal into a more compact binary signal. In the example of FIG. 1B, the receiver may receive four-level signaling such as PAM-4, the comparators may generate 3-line one-hot encoding at an intermediate bus 150, and the decoder may convert data on the 3-line one-hot bus to, e.g., data on a 2-bit parallel bus 152. Each of the comparators 130, 135, 140 may be formed as a differential pair of field-effect transistors (FETs) 155, with the sources of the two FETs connected together at a point referred to as the source connection 160, a current source 162 connected between the source connection 160 and ground, and the drain of each FET connected by a drain resistor 165 to the positive terminal of a power supply, which may also be referred to as Vcc. Each comparator has two inputs, one of which is connected to the input Vᵢₙ of the receiver, and one of which is connected to a threshold voltage; the threshold voltages are referred to as V_{Th,H}, V_{Th,M}, and V_{Th,L}, respectively, and may be selected so that each is approximately half-way between two adjacent levels of the multi-level signaling scheme, as illustrated in eye diagram 120 of FIG. 1A.

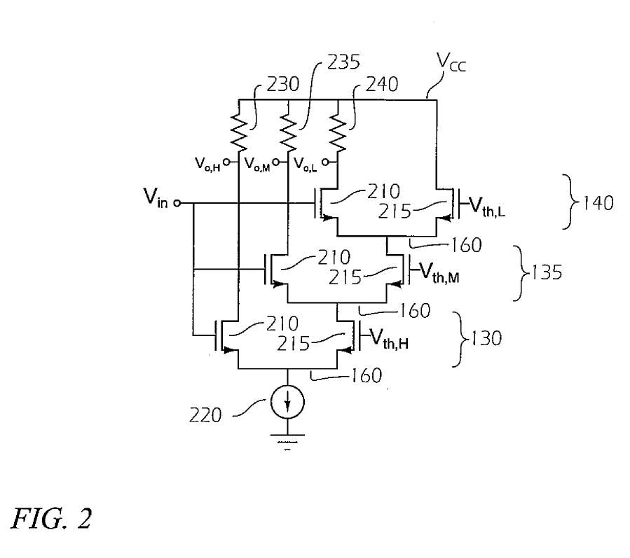

Referring to FIG. 2, in one embodiment a multi-level receiver may be constructed by stacking comparators, as illustrated in an example with three comparators 130, 135, 140, suitable for use in a PAM-4 receiver. Each comparator includes a first FET 210 and a second FET 215 configured as a differential pair with sources connected together at a source connection 160. One input of each comparator is connected to the receiver input Vᵢₙ, and the other input of each comparator is connected to a threshold voltage, i.e., to V_{Th,H}, V_{Th,M}, or V_{Th,L}. The source connection of the first comparator 130 is connected to one terminal of a current source 220, the other terminal of which is connected to ground. The drain connection of the first FET 210 of each of the comparators 130, 135, 140, is connected through a resistor, i.e., a respective one of the resistors 230, 235, 240, to Vcc. The drain connection of the second FET 215 of the first comparator 130 and the drain connection of the second comparator 135 are connected to the source connection 160 of the second comparator 135 and to the source connection of the third comparator 140, respectively, and the drain connection of the second FET 215 of the third comparator 130 is connected to Vcc. Three outputs V_{O,H}, V_{O,M}, and V_{O,L}, providing the received signal in inverted one-hot encoding, are connected to the drain of the first FET 210 of the first comparator 130, the drain of the first FET 210 of the second comparator 135, and the drain of the first FET 210 of the third comparator 140, respectively. As used herein, inverted one-hot encoding refers to an encoding scheme on a parallel bus, in which at most one of the lines represents a binary “0”, i.e., logic low, at any time.

Although the embodiment illustrated in FIG. 2 is composed of three comparators, each composed of a differential pair of FETs, the invention is not limited to this configuration. More or fewer comparators may be used; for example, N comparators may be used to construct a level detector for a multi-level receiver for multi-level signaling with N+1 levels. The elements forming each differential pair need not be FETs, but may be bipolar junction transistors, or other switches. In general a switch used in a differential pair may have a control terminal, a first switching terminal, and a second switching terminal. In the case of a bipolar junction transistor, for example, the base may be the control terminal and the collector and emitter may be the first and second switching terminal respectively, or the second and first switching terminal, respectively. In the case of a FET, the gate may be the control terminal and the drain and source may be the first and second switching terminal respectively, or the second and first switching terminal, respectively. Similarly, the switches may be P-channel FETs instead of N-channel FETs as illustrated in FIG. 2, or NPN or PNP transistors. If transistors are used for the switches, then, depending on the type of transistors used (e.g., NPN or PNP) the circuit may be inverted with respect to polarity, i.e., the resistors 230, 235, 240 may be connected to ground instead of Vcc, and the current source may be connected to Vcc. Moreover, although resistors are shown as the load elements between the drain connections of the first FETs 210 and Vcc, the invention is not thereby limited. Other elements may be used as load elements. A FET configured as a two-terminal device by connecting the gate and drain together may be used as a load element, for example.

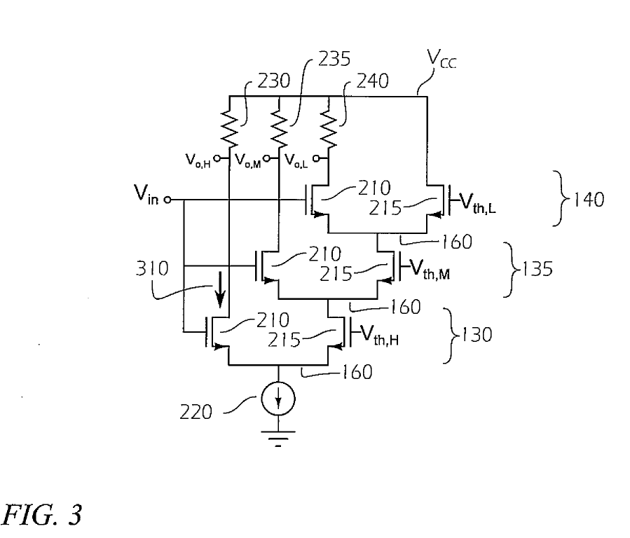

In operation, each of the three outputs V_{O,H}, V_{O,M}, and V_{O,L} is at a voltage of Vcc, customarily representing logic high or binary “1”, when the first FET 210 of the corresponding comparator is switched off, and at a voltage near ground, customarily representing logic low or binary “0”, when the first FET 210 of the corresponding comparator is switched on. Ordinarily, only one of the three outputs V_{O,H}, V_{O,M}, and V_{O,L}, is low at any time, and the other two are high; i.e., the encoding on the parallel bus formed by V_{O,H}, V_{O,M}, and V_{O,L} is inverted one-hot encoding. For example, referring to FIG. 3, when Vᵢₙ exceeds V_{Th,H}, as it does when the received input is approximately equal to the voltage value V₃, the first FET 210 of the first comparator 130 is switched on, i.e., it conducts from drain to source, and the second FET 215 of the first comparator 130 is switched off. In this state, the principal current path from Vcc to ground is through the first resistor 230, through the first FET 210 of the first comparator 130, as indicated by the arrow representing the current path 310, and through the current source 220. In this state, the output V_{O,H}, is low and the other two outputs, V_{O,M}, and V_{O,L}, are high.

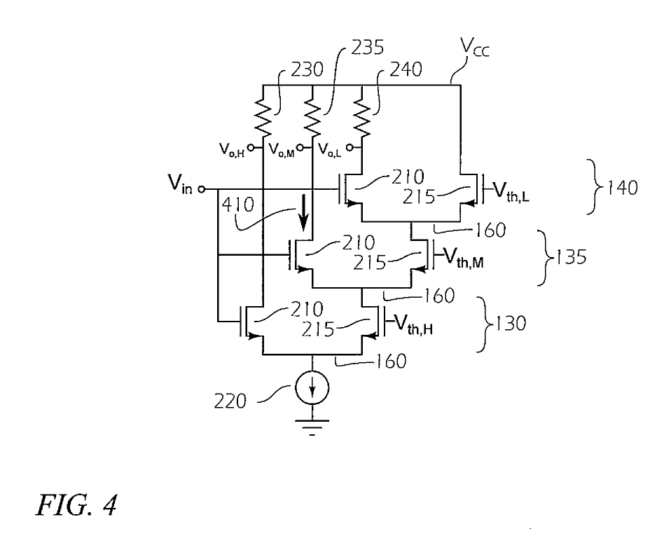

Referring to FIG. 4, when Vᵢₙ is greater than V_{Th,M}, but is less than V_{Th,H}, as it is when the received input is approximately equal to the voltage value V₂, the first FET 210 of the first comparator 130 is switched off, and the second FET 215 of the first comparator 130 is switched on, because Vᵢₙ is less than V_{Th,H}. The first FET 210 of the second comparator 135 is switched on, and the second FET 215 of the second comparator 135 is switched off, because Vᵢₙ exceeds V_{Th,M}. In this state the principal current path from Vcc to ground is through the second resistor 235, through the first FET 210 of the second comparator 135, as indicated by the arrow representing the current path 410, through the second FET 215 of the first comparator 130 and through the current source 220. In this state, the output V_{O,M}, is low and the other two outputs, V_{O,H}, and V_{O,L}, are high.

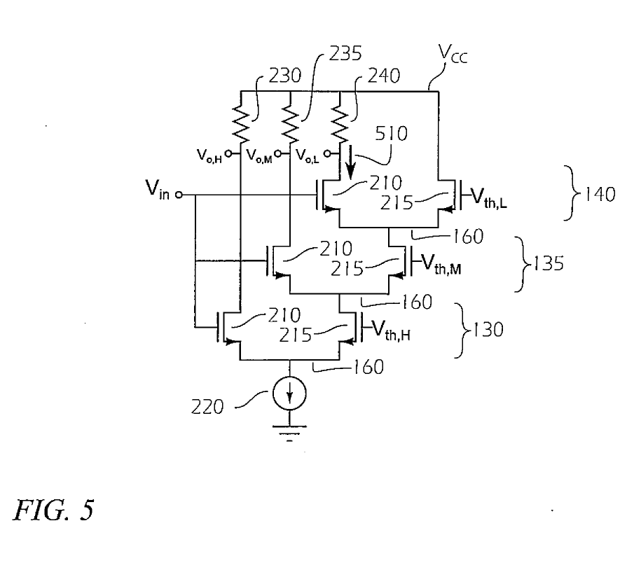

Referring to FIG. 5, when Vᵢₙ is greater than V_{Th,L} but is less than V_{Th,M}, as it is when the received input is approximately equal to the voltage value V₁, the first FET 210 of the first comparator 130 is switched off, and the second FET 215 of the first comparator 130 is switched on, because Vᵢₙ is less than V_{Th,H}. The first FET 210 of the second comparator 135 is switched off, and the second FET 215 of the second comparator 135 is switched on, because Vᵢₙ is less than V_{Th,M}. The first FET 210 of the third comparator 140 is switched on, and the second FET 215 of the third comparator 140 is switched off, because Vᵢₙ exceeds V_{Th,L}. In this state the principal current path from Vcc to ground is through the third resistor 240, through the first FET 210 of the third comparator 140, as indicated by the arrow representing the current path 510, through the second FET 215 of the second comparator 135, through the second FET 215 of the first comparator 130, and through the current source 220. In this state, the output V_{O,L}, is low and the other two outputs, V_{O,H}, and V_{O,M}, are high.

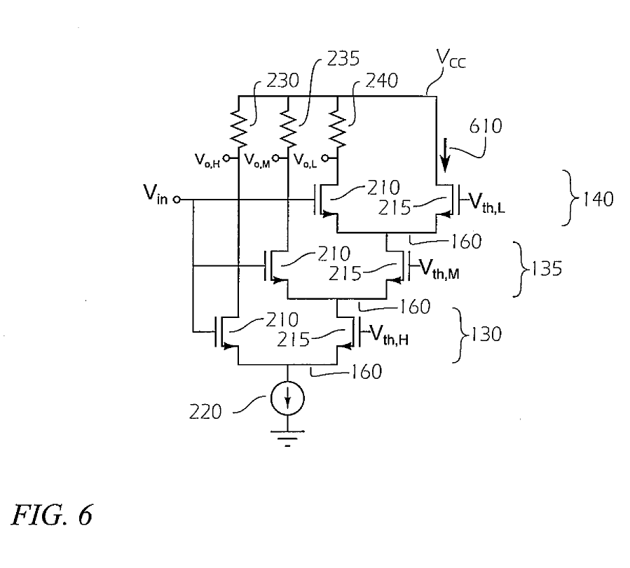

Referring to FIG. 6, when Vᵢₙ is less than V_{Th,L}, as it is when the received input is approximately equal to the voltage value V₀, the first FET 210 of the first comparator 130 is switched off, and the second FET 215 of the first comparator 130 is switched on, because Vᵢₙ is less than V_{Th,H}. The first FET 210 of the second comparator 135 is switched off, and the second FET 215 of the second comparator 135 is switched on, because Vᵢₙ is less than V_{Th,M}. The first FET 210 of the third comparator 135 is switched off, and the second FET 215 of the third comparator 135 is switched on, because Vᵢₙ is less than V_{Th,L}. In this state the principal current path from Vcc to ground is through the second FET 215 of the third comparator 140, as indicated by the arrow representing the current path 610, through the second FET 215 of the second comparator 135, through the second FET 215 of the first comparator 130, and through the current source 220. In this state, all three outputs V_{O,L}, V_{O,M}, and V_{O,H}, are high.

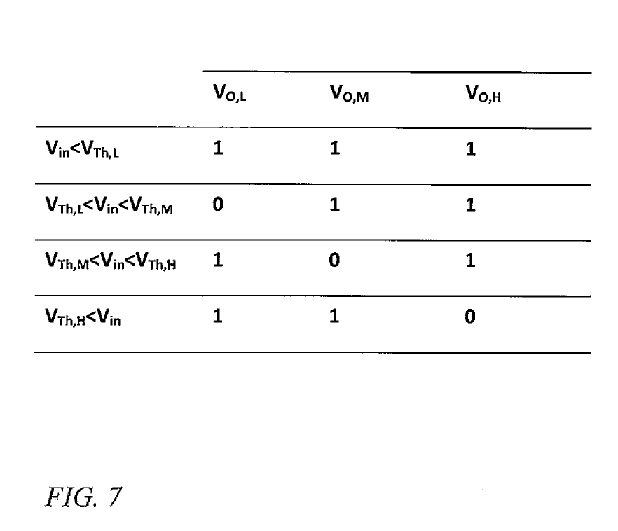

The truth table of FIG. 7 summarizes the behavior of the embodiment of FIG. 2. When Vᵢₙ is less than V_{Th,L}, all three outputs, V_{O,L}, V_{O,M}, and V_{O,H}, are high. When Vᵢₙ is greater than V_{Th,L}, and less than V_{Th,M}, V_{O,L}, is low, and V_{O,M}, and V_{O,H} are high. When Vᵢₙ is greater than V_{Th,M}, and less than V_{Th,H}, V_{O,M}, is low, and V_{O,L}, and V_{O,H} are high. When Vᵢₙ is greater than V_{Th,H}, V_{O,H} is low, and V_{O,L}, and V_{O,M}, are high.

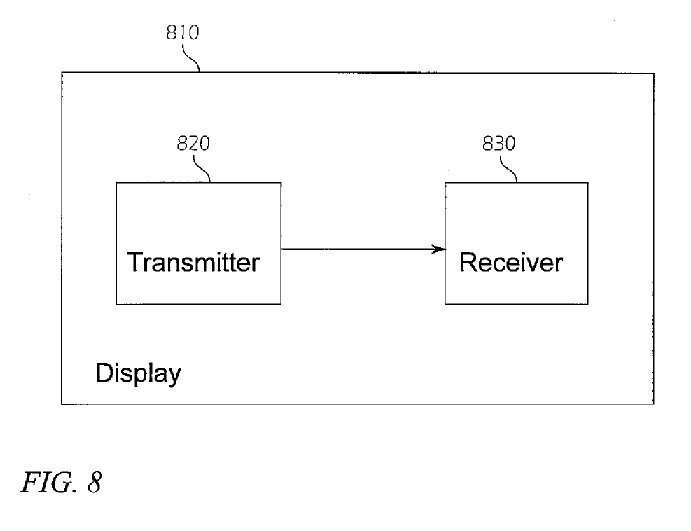

Referring to FIG. 8, in one embodiment a digital display 810, such as an organic light emitting diode display or a liquid crystal display in a television or a cell phone, includes a multi-level transmitter 820 transmitting data to a multi-level receiver 830. The multi-level receiver 830 may contain a level detector constructed according to an embodiment of the present invention. Although the present invention may be employed to transmit data between components of a display, the invention is not thereby limited, and it may be used in other applications in which data is transmitted from a transmitter to a receiver.

Although exemplary embodiments of a stacked comparator topology for multi-level signaling have been specifically described and illustrated herein, many modifications and variations will be apparent to those skilled in the art. Accordingly, it is to be understood that a stacked comparator topology for multi-level signaling constructed according to principles of this invention may be embodied other than as specifically described herein. The invention is also defined in the following claims, and equivalents thereof.

What is claimed is:

1. A system for receiving a multi-level signal, the system comprising:
a system input connection;
a first differential pair and a second differential pair;
each of the first differential pair and the second differential pair comprising a first switch and a second switch,
each of the first switch and the second switch comprising a first switching terminal, a second switching terminal, and a control terminal,
the second switching terminal of the first switch connected to the second switching terminal of the second switch,
the control terminal of the first switch of the first differential pair connected to the system input connection,
the control terminal of the first switch of the second differential pair connected to the system input connection,
the first terminal of the second switch of the first differential pair connected to:
the second switching terminal of the first switch of the second differential pair; and
the second switching terminal of the second switch of the second differential pair.

2. The system of claim 1, wherein at least one of the first switch or the second switch is a semiconductor switch.

3. The system of claim 2, wherein at least one the first switch or the second switch is a field effect transistor (PET).

4. The system of claim 2, wherein at least one the first switch or the second switch is a bipolar junction transistor (BJT).

5. The system of claim 1, wherein:
the control terminal of the second switch of the first differential pair is connected to a voltage source at a first threshold voltage, and
the control terminal of the first switch of the second differential pair is connected to a voltage source at a second threshold voltage.

6. The system of claim 5, wherein the first threshold voltage is greater than the second threshold voltage.

7. The system of claim 6, wherein:
the multi-level signal comprises three adjacent levels,
the first threshold voltage is half-way between a first adjacent pair of levels of the three adjacent levels, and
the second threshold voltage is half-way between a second adjacent pair of levels of the three adjacent levels.

8. The system of claim 1, wherein:
the second switching terminal of the first switch of the first differential pair and the second switching terminal of the second switch of the first differential pair are connected to a first terminal of a current source; and
the second terminal of the current source is connected to a first power supply connection.

9. The system of claim 8, wherein the first power supply connection is a ground connection of a power supply.

10. The system of claim 1, wherein:
the first switching terminal of the first switch of the first differential pair is connected to:
a first system output connection; and
a first terminal of a first load element;
the first switching terminal of the first switch of the second differential pair is connected to:
a second system output connection; and
a first terminal of a second load element;
a second terminal of the first load element is connected to a second power supply connection; and
a second terminal of the second load element is connected to the second power supply connection.

11. The system of claim 10, wherein the second power supply connection is a positive connection of a power supply.

12. The system of claim 10, wherein at least one the first switch or the second switch is a semiconductor switch.

13. The system of claim 12, wherein at least one the first switch or the second switch is a field effect transistor (FET).

14. The system of claim 12, wherein at least one the first switch or the second switch is a bipolar junction transistor (BJT).

15. The system of claim 10, wherein:
the control terminal of the second switch of the first differential pair is connected to a voltage source at a first threshold voltage, and
the control terminal of the first switch of the second differential pair is connected to a voltage source at a second threshold voltage.

16. The system of claim 15, wherein the second threshold voltage is greater than the first threshold voltage.

17. The system of claim 16, wherein:
the multi-level signal comprises three adjacent levels, and
the first threshold voltage is half-way between a first adjacent pair of levels of the three adjacent levels; and
the second threshold voltage is half-way between a second adjacent pair of levels of the three adjacent levels.

18. The system of claim 10, wherein at least one of the first load element or the second load element is a resistor.

19. The system of claim 10, wherein
at least one of the first load element or the second load element is a third switch,
the third switch comprising a first switching terminal, a second switching terminal, and a control terminal,
the control terminal of the third switch being connected to the first switching terminal of the third switch.

20. The system of claim 19, wherein the third switch is a FET comprising a source terminal, a drain terminal, and a gate terminal, the drain terminal being the first switching terminal of the third switch, the source terminal being the second switching terminal of the third switch, and the gate being the control terminal of the third switch.
